(19) United States
(12) Patent Application Publication
(10) Pub. No.: US 2014/0055888 A1
(43) Pub. Date: Feb. 27, 2014

(54) POWER MODULE AND METHOD OF OPERATING A POWER MODULE

(71) Applicants: Filippo Chimento, Vasteras (SE); Georgios Demetriades, Vasteras (SE); Hamit Duran, Turgi (CH)

(72) Inventors: Filippo Chimento, Vasteras (SE); Georgios Demetriades, Vasteras (SE); Hamit Duran, Turgi (CH)

(73) Assignee: ABB RESEARCH LTD, Zurich (CH)

(21) Appl. No.: 14/116,190

(22) PCT Filed: May 10, 2011
(86) PCT No.: PCT/EP11/57507

§ 371 Date: Nov. 12, 2013

(51) Int. Cl. H03K 17/08

(52) U.S. Cl. CPC H03K 17/08
USPC 361/18

(57) ABSTRACT

A power module (10), which is operated serially with other similar power modules in a converter valve, comprises a plurality of submodules (13a-d) connected in parallel, wherein each of the submodules includes one or several semiconductor elements connected in parallel and the power kind module is of the kind wherein if one of the submodules starts malfunctioning, the remaining ones of the submodules assume a closed circuit. The power module further comprises, for each of the submodules, a separate driver unit (14a-d) for driving the one or several semiconductor elements of that submodule, and a separate control unit (11a-d) for controlling the driver unit of that submodule. The power module may be used in HVDC or SVC apparatuses.

### TECHNICAL FIELD

The present invention is related to electric power converters. In particular, the invention relates to a power module and to a converter valve comprising a plurality of such power modules connected in series. The invention also relates to a high voltage direct current apparatus and to a static var compensator apparatus comprising such a converter valve and to a method of operating a power module.

### BACKGROUND OF THE INVENTION

Voltage source converters (VSC) comprises a plurality of semiconductor switches such as IGBT power modules. They are often used in high-voltage direct current (HVDC) applications for converting direct current to alternating current and vice versa or in static var compensators (SVC) for reactive power compensation in power transmission systems. Other Flexible Alternating Current Transmission Systems (FACTS) applications are of course also possible, as will be appreciated by the skilled person.

The semiconductor switches can, for example, be connected in series, where each switch is capable of maintaining a part of the voltage applied over the converter. Known power semiconductors are capable of holding a voltage of 1 to 6 kV. By series connection of a plurality of such switches a converter may maintain a voltage within a range of 10 to 500 kV. Each switch comprises a plurality of semiconducting elements that may be connected in series and/or in parallel to achieve a performance of desire. The series connection will increase the voltage capability and the parallel connection will increase the current capability.

IGBT power modules are often preferable since they combine good power handling ability with properties which make them well suited for connection in series.

A power switch has typically a design, which comprises a plurality of converter valves, each of which comprising a plurality of power modules connected in series. Each of the power modules comprises a plurality of semiconductor elements such as IGBT's connected in parallel.

Each of the power modules is designed to handle a determined part of the overall voltage of the converter valve and to transfer the total current of the converter valve. If one of the semiconducting elements of a power module fails, that power module will no longer be capable of holding a voltage difference. Still when the whole converter valve is controlled into a closed circuit, a part of the current or the total current will pass the faulty semiconductor and thus develop heat.

To avoid such a situation the semiconducting element used today comprises a special feature of assuming a closed circuit after a fatal breakdown has occurred. By assuming a closed circuit no heat will be generated in the faulty semiconductor. Thus, in the situation described the semiconducting elements in one power module are still capable of transferring the same current as would have been when all semiconducting element were in operation. Hence, when one of the semiconductors in a power module fails the other semiconductors of that module are controlled to assume a steady closed circuit. This will result in the module no longer being capable of holding a voltage but still conduct the current without heat generation. This functionality is known as SCFM (short circuit failure mode) and may be realized by means of an aluminium plate arranged on top of the power module IGBT silicon chip. A failure usually leads to a break-through and as a result the aluminium plate and the silicon chip melt and forms a conductive aluminium-silicon alloy, see e.g. US 2006/0118816.

From a voltage aspect, however, the failing module will not withstand any voltage since at least one semiconducting unit is always short circuited. This has the effect that the voltage applied over the converter valve which normally is split up by a plurality of switching units now has to be split by the same number but one. Since the number of series connected units are typically in the range of 100 to 500 the voltage overload is in the range of 0.2 to 1%. This is fully within the voltage overload capacity of the semiconducting element.

The lifetime of the conductive alloy disclosed in US 2006/0118816, that is, the time during which it maintains its low-ohmic state, is limited and is usually shorter than the targeted maintenance interval of a typical HVDC or SVC system. As a result neighboring IGBT chips start to melt and form low-ohmic alloys. This process is known as a SCFM transition and can under certain circumstances lead to an unwanted failure of the entire converter valve.

SCFM transitions may be avoided by using the so-called kill switch principle, that is, keeping the undamaged IGBT's of the power module actively in on-state, see e.g. WO 2006/104430 which discloses a solution based on a current sensing device and a controlling device for controlling the undamaged IGBT's in response to the output of the current sensing device. However, a problem with this principle is that in case of a gate-emitter short circuit, a high current is drawn from the gate voltage supply, which can place the entire gate control unit, and thus the entire power module, out of operation.

### SUMMARY OF THE INVENTION

An object of the present invention is therefore to provide a power module for being operated serially with other power modules in a converter valve, by which at least some of the drawbacks as disclosed above in the background chapter are avoided or at least alleviated.

A particular object is to provide a power module for being operated serially with other power modules in a converter valve, which avoids failure of the entire power module in case a gate-emitter short circuit of a semiconductor element draws high currents from its voltage supply.

It is a further object of the invention to provide a power module for being operated serially with other power modules in a converter valve, which is simple, robust, and reliable.

These objects, among others, are according to a first aspect of the present invention attained by a power module comprising a plurality of submodules connected in parallel, wherein each of the submodules includes one or several semiconductor elements, e.g. IGBT's, connected in parallel. The power module is of the kind wherein if one of the submodules starts malfunctioning, the remaining ones of the submodules assume a closed circuit. To maintain the current capability at acceptable limits in case of a failure, the power module comprises, for each of the submodules, a separate driver unit, gate driver in case the semiconductor elements are IGBT's, for driving the one or several semiconductor elements of that submodule. Further, the power module comprises, for each of the submodules, a separate control unit for controlling the driver unit of that submodule. The driver unit and the control unit of each submodule may be integrated into a single unit, a gate unit in case the semiconductor elements are IGBT's.

A converter valve in accordance with the present invention comprises a plurality of the power module depicted above connected in series and an HVDC or SVC apparatus in accordance with the invention comprises a plurality of such converter valves. The inventive power module may as well be used in other applications where series, and/or parallel, connection of semiconductor switches is required.

It is yet a further object of the invention to provide a method of operating a power module that fulfils any of the above objects.

This object, among others, are according to a second aspect of the present invention attained by a method of operating a power module, which is serially connected with other power modules in a converter valve, the power module comprising a plurality of submodules connected in parallel, wherein each of the submodules includes one or several semiconductor elements, preferably IGBT's, connected in parallel and the power module is of the kind wherein if one of the submodules starts malfunctioning, the remaining ones of the submodules assume a closed circuit. According to the method, each of the submodules of the power module is driven by a separate driver unit and each driver unit is controlled by a separate control unit, conveniently integrated with the respective driver unit.

An advantage of the invention is that in case of a high current drawn by a gate-emitter short circuit in one IGBT, leading to the driver unit connected thereto being damaged, only the submodule comprising the IGBT will be damaged since the other submodules have separate driver and control units. Hereby, the current capability of the power module will be held at an acceptable limit.

Further advantages include:
Possible selectivity of failures on submodule level
Integration of the circuital solution into the gate driving system
Circuit not subject to the module thermal field
Possibility of fusing out the failure in the immediate proximity of the gate unit power board
Compact solution for the electronic system composed by optical power supply+kill switch circuit+fusing element
Possibility to adapt to several types of IGBT packages (i.e. HiPak, different subs number StakPak)

### BRIEF DESCRIPTION OF THE DRAWINGS

Other features and advantages of the present invention will become more apparent to a person skilled in the art from the following detailed description in conjunction with the appended drawings in which:

FIG. 1 illustrates schematically a power module according to an embodiment of the present invention, and

FIG. 2 illustrates schematically a power module according to a further embodiment of the invention.

### DESCRIPTION OF EMBODIMENTS

In the following description, for purposes of explanation and not limitation, specific details are set forth such as particular architectures, interfaces, techniques, etc. in order to provide a thorough understanding of the invention. However, it will be apparent to those skilled in the art that the invention may be practiced in other embodiments that depart from these specific details. In other instances, detailed descriptions of well-known devices, circuits, and methods are omitted so as not to obscure the description of the invention with unnecessary detail.

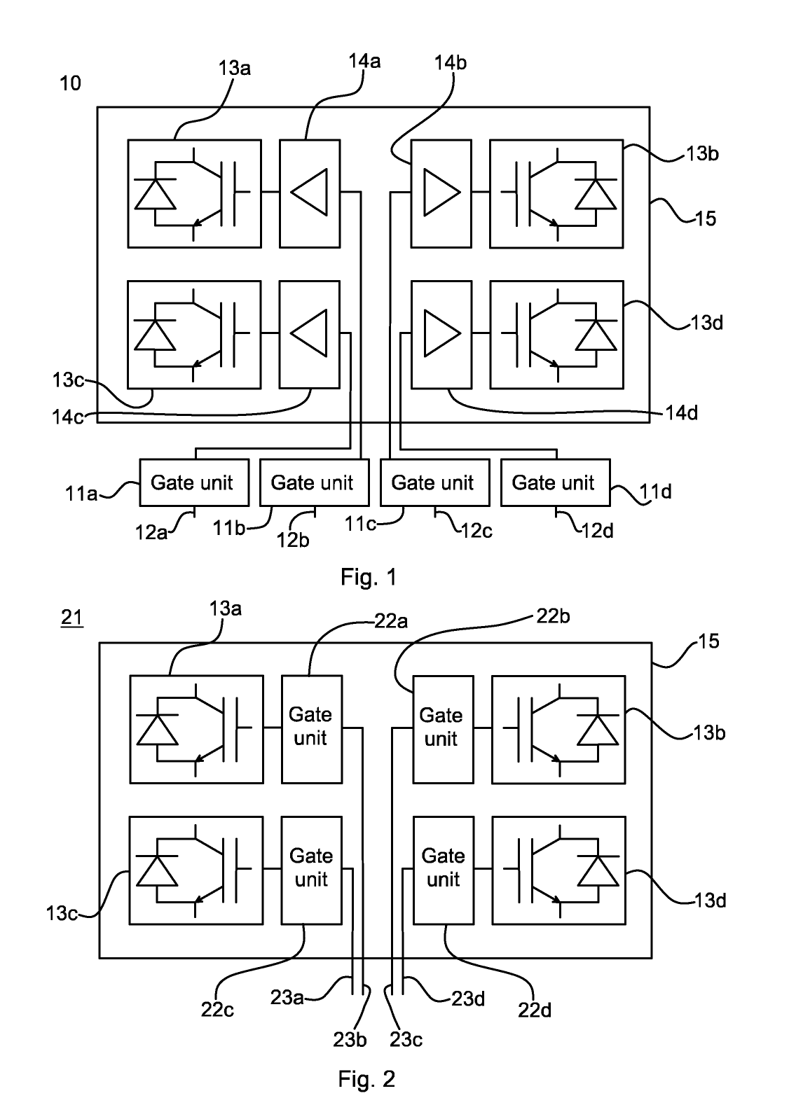

A high voltage converter circuit comprises normally three phase legs connected to a three-phase alternating voltage network. Each phase leg of a high voltage converter circuit comprises typically at least a first and second converter valve: each converter valve comprises a plurality of power modules, of which one such power module 10 according to an embodiment of the invention is disclosed in FIG. 1. A plurality of such power modules 10 is connected in series to form the converter valve.

The power module 10 comprises a plurality of submodules 13a-d arranged within an explosion-proof housing 15. Each of the submodules 13a-d includes one or several semiconductor elements, such as IGBT's, connected in parallel. In one version the submodules include each a single IGBT. The number of submodules may be less, higher, or much higher than the illustrated four.

The submodules 13a-d are connected in parallel. Thus, the submodules 13a-d provides each a portion of the current capability of the power module 10.

Further, the power module 10 is of the kind wherein if one of the submodules, e.g. 13a, starts malfunctioning, the remaining ones, e.g. 13b-d, of the submodules assume a closed circuit. One example of such power module is described in WO 2006/104430, the contents of which being hereby incorporated by reference. If the malfunctioning submodule comprises a plurality of IGBT's, the ones still operating assume as well a closed circuit.

According to the present invention, the power module 10 comprises, for each of the submodules 13a-d, a separate driver unit 14a-d for driving the one or several semiconductor elements of that submodule 13a-d. The driver units 14a-d are conveniently located within the explosion-proof housing 15. In case the semiconductor elements are IGBT's the separate driver units 14a-d are gate drivers.

The driver units 14a-d are each connected to a respective one of a plurality of control unit 11a-d for controlling of the driver unit. The control units 11a-d are each also provided with power supply for the semiconductor elements of that submodule 13a-d. Conveniently, the control units 11a-d are located outside the explosion-proof housing 15. The control units 11a-d, which are gate units in case the semiconductor elements are IGBT's, have each a respective input 12a-d to be connected to external control circuitry.

FIG. 2 discloses a power module 21 according to a further embodiment of the invention, which differs from the embodiment of FIG. 1 regarding the control and driver units. Here, each of the submodules 13a-d is provided with a separate control and driver unit 22a-d arranged next to the submodule 13a-d within the explosion-proof housing 15. In case the semiconductor elements are IGBT's the control and driver units 22a-d are gate units with in-built drivers and gate voltage power supply to the IGBT's. The power module 21 has inputs 23a-d to be connected to external control circuitry, the number of which corresponding to the number of submodules 13a-d in the power module 21.

It shall be appreciated that instead of having integrated control and driver units 22a-d, each of the submodule 13a-d may be provided with a separate driver unit and a separate control unit arranged within or outside of the explosion-proof housing 15.

A plurality of the power module of the present invention are stacked and are serially connected to form a converter valve of the present invention. An HVDC or SVC apparatus of the present invention is provided with a plurality of such inventive converter valves.

It shall be appreciated that the invention is also related to a method of operating a power module of the above depicted kind. The method features the step of driving each of the submodules of the power module by a separate driver unit.

While the invention has been described in connection with what is presently considered to be most practical and preferred embodiments, it is to be understood that the invention is not to be limited to the disclosed embodiments, but on the contrary, is intended to cover various modifications and equivalent arrangements. Therefore the invention is only to be limited by the following claims.

1.-11. (canceled)

12. A power module for being operated serially with other power modules in a converter valve, the power module comprising a plurality of submodules connected in parallel, wherein each of the submodules includes one or several semiconductor elements connected in parallel and the power module is of the kind wherein if one of the submodules starts malfunctioning, the remaining ones of the submodules assume a closed circuit,
wherein the power module comprises, for each of the submodules, a separate driver unit driving the one or several semiconductor elements of that submodule and a separate control unit for controlling the driver unit of that submodule,
wherein the power module comprises an explosion-proof housing in which the submodules and the separate driver units are arranged, the driver units being gate drivers, and
wherein the separate control units are arranged outside of the explosion-proof housing.

13. The power module according to claim 12 wherein the semiconductor elements are IGBT's.

14. A converter valve comprising a plurality of the power modules according to claim 12 connected in series.

15. A converter valve comprising a plurality of the power modules according to claim 13 connected in series.

16. An HVDC apparatus comprising the converter valve of claim 14.

17. An SVC apparatus comprising the converter valve of claim 14.
